(19) United States
(12) Patent Application Publication
(10) Pub. No.: US 2022/0397603 A1
(43) Pub. Date: Dec. 15, 2022

(54) HYSTERESIS SIGNAL DETECTION CIRCUIT

(71) Applicant: ZHUHAI FUDAN INNOVATION INSTITUTE, Zhuhai (CN)

(72) Inventor: Liang Zou, Zhuhai (CN)

(73) Assignee: ZHUHAI FUDAN INNOVATION INSTITUTE, Zhuhai (CN)

(21) Appl. No.: 17/771,813

(22) PCT Filed: Dec. 9, 2019
(86) PCT No.: PCT/CN2019/123886

§ 371 Date: Apr. 26, 2022

(51) Int. Cl. G01R 31/317

(52) U.S. Cl. CPC G01R 31/317

(57) ABSTRACT

The present invention discloses a hysteresis signal detection circuit, comprising: a first MOS transistor, a second MOS transistor, an inverter INV1, an inverter INV2 and an inverter INV3. A gate of the first MOS transistor is connected with an input end, and a drain of the first MOS transistor is connected with an output end through the inverter INV1, the inverter INV2 and the inverter INV3 successively; a source of the first MOS transistor is connected with a drain of the second MOS transistor, and a gate of the second MOS transistor is connected between the inverter INV1 and the inverter INV2; and a resistor R1 is connected between a source and the drain of the second MOS transistor. In the present invention, not only the hysteresis voltage can be adjusted through current and resistance values, which is flexible, but also the hysteresis voltage may not change with power voltage.

### TECHNICAL FIELD

The present invention relates to the technical field of logic signal detection, and particularly relates to a hysteresis signal detection circuit.

### BACKGROUND

A detection circuit is used to detect an input voltage signal of a chip. The traditional logic signal detection circuit with hysteresis is shown in FIG. 1. The hysteresis voltage of the detection circuit cannot be adjusted flexibly, and the upper and lower limit voltage and the hysteresis voltage may change with the power voltage.

Therefore, how to provide a hysteresis signal detection circuit with flexibly adjustable hysteresis voltage becomes an urgent problem to be solved by those skilled in the art.

### SUMMARY

In view of this, the present invention provides a hysteresis signal detection circuit. Not only the hysteresis voltage can be adjusted through current and resistance values, which is flexible, but also the hysteresis voltage may not change with the power voltage.

To achieve the above purpose, the present invention adopts the following technical solution:

A hysteresis signal detection circuit comprises: a first MOS transistor, a second MOS transistor, an inverter INV1, an inverter INV2 and an inverter INV3, wherein a gate of the first MOS transistor is connected with an input end, and a drain of the first MOS transistor is connected with an output end through the inverter INV1, the inverter INV2 and the inverter INV3 successively; a source of the first MOS transistor is connected with a drain of the second MOS transistor, and a gate of the second MOS transistor is connected between the inverter INV1 and the inverter INV2; and a resistor R1 is connected between a source and the drain of the second MOS transistor.

Preferably, one end of the inverter INV1, the inverter INV2 and the inverter INV3 is connected with a power VDD, and the other end is connected with a power VSS.

Preferably, a resistor R2 is arranged between the first MOS transistor and the input end.

Preferably, the first MOS transistor adopts an N-type MOS transistor M1, and the second MOS transistor adopts an N-type MOS transistor M2.

Preferably, the gate of the N-type MOS transistor M1 is connected with the input end, the drain of the N-type MOS transistor M1 is respectively connected with the inverter INV1 and the power VDD, and the inverter INV1 is connected with the output end through the inverter INV2 and the inverter INV3 successively, the source of the N-type MOS transistor M1 is connected with the drain of the N-type MOS transistor M2, the gate of the N-type MOS transistor M2 is connected between the inverter INV1 and the inverter INV2, and the source of the N-type MOS transistor M2 is connected with the power VSS; and a resistor R1 is connected between the source and the drain of the N-type MOS transistor M2.

Preferably, the first MOS transistor adopts a P-type MOS transistor M3, and the second MOS transistor adopts a P-type MOS transistor M4.

Preferably, the gate of the P-type MOS transistor M3 is connected with the input end, the drain of the P-type MOS transistor M3 is respectively connected with the inverter INV1 and the power VSS, and the inverter INV1 is connected with the output end through the inverter INV2 and the inverter INV3 successively; the source of the P-type MOS transistor M3 is connected with the drain of the P-type MOS transistor M4, the gate of the P-type MOS transistor M4 is connected between the inverter INV1 and the inverter INV2, and the source of the P-type MOS transistor M4 is connected with the power VDD; and a resistor R1 is connected between the source and the drain of the P-type MOS transistor M4.

The present invention has the following beneficial effects:

The circuit of the present invention is simple and easy to realize, and can be used for the detection of the input voltage signal of the chip. Addition of hysteresis in the detection circuit can effectively remove the burr of an output signal caused by noise jitter in the input signal. In addition, the hysteresis voltage of the present invention can be adjusted through curent and resistance values, which is flexible, and the hysteresis voltage may not change with the power voltage.

### DESCRIPTION OF DRAWINGS

To more clearly describe the technical solution in the embodiments of the present invention or in the prior art, the drawings required to be used in the description of the embodiments or the prior art will be simply presented below. Apparently, the drawings in the following description are merely the embodiments of the present invention, and for those ordinary skilled in the art, other drawings can also be obtained according to the provided drawings without contributing creative labor.

FIG. 1 is a traditional logic signal detection circuit with hysteresis.

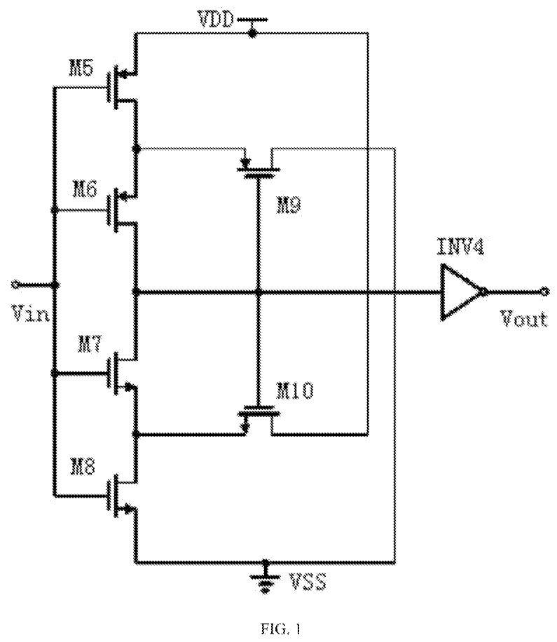

FIG. 2 is an N-type MOS implementation circuit of the present invention.

FIG. 3 is a P-type MOS implementation circuit of the present invention.

### DETAILED DESCRIPTION

The technical solution in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

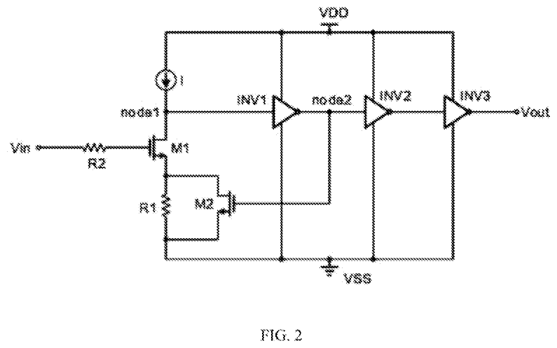

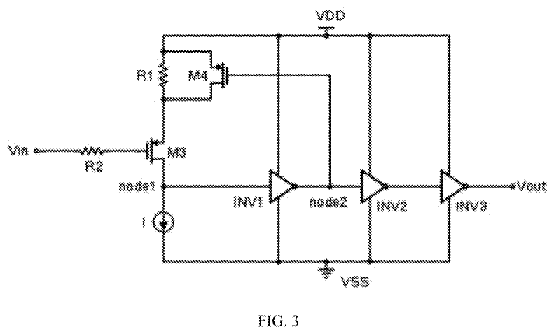

By referring to FIGS. 2-3, the present invention provides a hysteresis signal detection circuit, comprising: a first MOS transistor, a second MOS transistor, an inverter INV1, an inverter INV2 and an inverter INV3, wherein a gate of the first MOS transistor is connected with an input end, and a drain of the first MOS transistor is connected with an output end through the inverter INV1, the inverter INV2 and the inverter INV3 successively, a source of the first MOS transistor is connected with a drain of the second MOS transistor, and a gate of the second MOS transistor is connected between the inverter INV1 and the inverter INV2; a resistor R1 is connected between a source and the drain of the second MOS transistor. One end of the inverter INV1, the inverter INV2 and the inverter INV3 is connected with a power VDD, and the other end is connected with a power VSS.

In another embodiment, a resistor R2 is arranged between the first MOS transistor and the input end. The resistor R2 is arranged for ESD protection.

In another embodiment, by referring to FIG. 2, the first MOS transistor adopts an N-type MOS transistor M1, and the second MOS transistor adopts an N-type MOS transistor M2. The gate of the N-type MOS transistor M1 is connected with the input end, and the drain of the N-type MOS transistor M1 is respectively connected with the inverter INV1 and the power VDD; a current source is arranged between the power VDD and the drain of the N-type MOS transistor M1; and the inverter INV1 is connected with the output end through the inverter INV2 and the inverter INV3 successively; the source of the N-type MOS transistor M1 is connected with the drain of the N-type MOS transistor M2, the gate of the N-type MOS transistor M2 is connected between the inverter INV1 and the inverter INV2, and the source of the N-type MOS transistor M2 is connected with the power VSS; and a resistor R1 is connected between the source and the drain of the N-type MOS transistor M2.

The detection of the input end Vin voltage from low to high:

When the input end Vin voltage is VSS, the N-type MOS transistor M1 is turned off, and node1 voltage is VDD. Through the inverter INV1, node2 is VSS. Thus, the N-type MOS transistor M2 is in an off state, and the output end Vout voltage is VSS. When the input end Vin changes from low to high, if Vth is the threshold voltage of the N-type MOS transistor M1, Vsat is overdrive voltage when the current of the N-type MOS transistor M1 is I. When the input end Vin voltage reaches and exceeds Vth+Vsat+I*R1, node1 voltage changes from VDD to very low voltage. After amplification by the inverter INV1, node2 voltage rises to VDD, and the output end Vout voltage also flips to VDD. At this time, the rising edge change of the input voltage is detected. The N-type MOS transistor M2 enters a conducting state.

The detection of the input end Vin from high to low:

If the conducting voltage drop of the N-type MOS transistor M1 and the N-type MOS transistor M2 can be ignored, when the input end Vi decreases to and is lower than Vth+Vsat, the node1 voltage rises from VSS to VDD. After amplification by the inverter INV1, the node2 voltage is reduced to VSS, and the output end Vout voltage also flips to VSS. At this time, the falling edge change of the input voltage is detected. The N-type MOS transistor M2 enters an off state.

To sum up, the upper limit voltage in the detection of the input signal voltage is Vth+Vsat+I*R1, the lower limit voltage is Vth+Vsat, and the hysteresis voltage is I*R1. The values of I and the resistor R1 can be adjusted to adjust the hysteresis voltage.

The present invention adopts a realization circuit of the N-type transistor M1 and the N-type MOS transistor M2, and voltage differences from the upper limit voltage and the lower limit voltage to the ground may not change with the power voltage.

In another embodiment, by referring to FIG. 3, the first MOS transistor adopts a P-type MOS transistor M3, and the second MOS transistor adopts a P-type MOS transistor M4. The gate of the P-type MOS transistor M3 is connected with the input end, and the drain of the P-type MOS transistor M3 is respectively connected with the inverter INV1 and the power VSS; a current source is arranged between the power VSS and the drain of the P-type MOS transistor M3; and the inverter INV1 is connected with the output end through the inverter INV2 and the inverter INV3 successively; the source of the P-type MOS transistor M3 is connected with the drain of the P-type MOS transistor M4, the gate of the P-type MOS transistor M4 is connected between the inverter INV1 and the inverter INV2, and the source of the P-type MOS transistor M4 is connected with the power VDD; and a resistor R1 is connected between the source and the drain of the P-type MOS transistor M4.

The detection of the input end Vin voltage from low to high:

When the input end Vin voltage is VSS, the P-type MOS transistor M3 is conducted, and node1 voltage is VDD. Through the inverter INV1, node2 is VSS. Thus, the P-type MOS transistor M4 is in a conducting state, and the output end Vout voltage is VSS. When the input end Vin changes from low to high, if Vth is the threshold voltage of the P-type MOS transistor M3, Vsat is overdrive voltage when the current of the P-type MOS transistor M3 is I. When the input end Vin voltage reaches and exceeds Vth+Vsat+I*R1, node1 voltage changes from VDD to very low voltage. After amplification by the inverter INV1, node2 voltage rises to VDD, and the output end Vout voltage also flips to VDD. At this time, the rising edge change of the input voltage is detected. The P-type MOS transistor M4 enters a conducting state.

The detection of the input end Vin from high to low:

If the conducting voltage drop of the P-type MOS transistor M3 and the P-type MOS transistor M4 can be ignored, when the input end Vin decreases to and is lower than Vth+Vsat, the node1 voltage rises from VSS to VDD. After amplification by the inverter INV1, the node2 voltage is reduced to VSS, and the output end Vout voltage also flips to VSS. At this time, the falling edge change of the input voltage is detected. The P-type MOS transistor M4 enters an off state.

To sum up, the upper limit voltage in the detection of the input signal voltage is Vth+Vsat+I*R1, the lower limit voltage is Vth+Vsat, and the hysteresis voltage is I*R1. The values of I and the resistor R1 can be adjusted to adjust the hysteresis voltage.

The present invention adopts a realization circuit of the P-type MOS transistor M3 and the P-type MOS transistor M4, and voltage differences from the upper limit voltage and the lower limit voltage to a power supply may not change with the power voltage.

The circuit of the present invention is simple and easy to realize, and can be used for the detection of the input voltage signal of the chip. Addition of hysteresis in the detection circuit can effectively remove the burr of an output signal caused by noise jitter in the input signal. In addition, the hysteresis voltage of the present invention can be adjusted through current and resistance values, which is flexible, and the hysteresis voltage may not change with the power voltage.

Each embodiment in the description is described in a progressive way. The difference of each embodiment from each other is the focus of explanation. The same and similar parts among all of the embodiments can be referred to each other. For a device disclosed by the embodiments, because the device corresponds to a method disclosed by the embodiments, the device is simply described. Refer to the description of the method part for the related part.

The above description of the disclosed embodiments enables those skilled in the art to realize or use the present invention. Many modifications to these embodiments will be apparent to those skilled in the art. The general principle defined herein can be realized in other embodiments without departing from the spirit or scope of the present invention. Therefore, the present invention will not be limited to these embodiments shown herein, but will conform to the widest scope consistent with the principle and novel features disclosed herein.

What is claimed is:

1. A hysteresis signal detection circuit, comprising: a first MOS transistor, a second MOS transistor, an inverter INV1, an inverter INV2 and an inverter INV3, wherein a gate of the first MOS transistor is connected with an input end, and a drain of the first MOS transistor is connected with an output end through the inverter INV1, the inverter INV2 and the inverter INV3 successively; a source of the first MOS transistor is connected with a drain of the second MOS transistor, and a gate of the second MOS transistor is connected between the inverter INV1 and the inverter INV2; and a resistor R1 is connected between a source and the drain of the second MOS transistor.

2. The hysteresis signal detection circuit according to claim 1, wherein one end of the inverter INV1, the inverter INV2 and the inverter INV3 is connected with a power VDD, and the other end is connected with a power VSS.

3. The hysteresis signal detection circuit according to claim 2, wherein a resistor R2 is arranged between the first MOS transistor and the input end.

4. The hysteresis signal detection circuit according to claim 3, wherein the first MOS transistor adopts an N-type MOS transistor M1, and the second MOS transistor adopts an N-type MOS transistor M2.

5. The hysteresis signal detection circuit according to claim 4, wherein the gate of the N-type MOS transistor M1 is connected with the input end, the drain of the N-type MOS transistor M1 is respectively connected with the inverter INV1 and the power VDD, and the inverter INV1 is connected with the output end through the inverter INV2 and the inverter INV3 successively; the source of the N-type MOS transistor M1 is connected with the drain of the N-type MOS transistor M2, the gate of the N-type MOS transistor M2 is connected between the inverter INV1 and the inverter INV2, and the source of the N-type MOS transistor M2 is connected with the power VSS; and a resistor R1 is connected between the source and the drain of the N-type MOS transistor M2.

6. The hysteresis signal detection circuit according to claim 3, wherein the first MOS transistor adopts a P-type MOS transistor M3, and the second MOS transistor adopts a P-type MOS transistor M4.

7. The hysteresis signal detection circuit according to claim 6, wherein the gate of the P-type MOS transistor M3 is connected with the input end, the drain of the P-type MOS transistor M3 is respectively connected with the inverter INV1 and the power VSS, and the inverter INV1 is connected with the output end through the inverter INV2 and the inverter INV3 successively; the source of the P-type MOS transistor M3 is connected with the drain of the P-type MOS transistor M4, the gate of the P-type MOS transistor M4 is connected between the inverter INV1 and the inverter INV2, and the source of the P-type MOS transistor M4 is connected with the power VDD; and a resistor R1 is connected between the source and the drain of the P-type MOS transistor M4.
